(19) United States
(12) Patent Application Publication
(10) Pub. No.: US 2022/0130770 A1
(43) Pub. Date: Apr. 28, 2022

(54) Copper Filled Recess Structure and Method for Making the Same

(71) Applicant: Shanghai Huali Integrated Circuit Corporation, Shanghai (CN)

(72) Inventors: Zhaoqin Zeng, Shanghai (CN); Yu Bao, Shanghai (CN)

(73) Assignee: Shanghai Huali Integrated Circuit Corporation, Shanghai (CN)

(21) Appl. No.: 17/164,941

(22) Filed: Feb. 2, 2021

(30) Foreign Application Priority Data
Oct. 28, 2020 (CN) 202011171811.X

(51) Int. Cl. H01L 23/532; H01L 23/522; H01L 21/768; H01L 21/02

(52) U.S. Cl. CPC H01L 23/53238; H01L 23/5226; H01L 21/76877; H01L 21/02458; H01L 21/76873

(57) ABSTRACT

The present application discloses a copper filled recess structure, which comprises a recess formed in a first dielectric layer; a block layer is formed on the bottom surface and side surfaces of the recess; a cobalt layer and a ruthenium layer are formed on the surface of the block layer; a copper layer completely fills the recess; a supportive nucleation film layer of the copper layer is formed by superposing the cobalt layer and the ruthenium layer. The present application further discloses a method for making a copper filled recess structure. Since the copper layer in the present application does not contain a copper seed layer and completely consists of the electrochemically-plated copper film, the ability of filling copper in the recess can be improved, and it is especially suitable for use as a copper connection and a via at a process node of less than 14 nm.

### CROSS-REFERENCE TO RELATED APPLICATIONS

This application claims priority to Chinese Patent Application No. 202011171811.X, filed on Oct. 28, 2020, and entitled “Copper Filled Recess Structure and Method for Making the Same”, the disclosure of which is incorporated herein by reference in its entirety.

### TECHNICAL FIELD

The present application relates to the field of semiconductor integrated circuit manufacturing, and in particular to a copper filled recess structure. The present application further relates to a method for making the copper filled recess structure.

### BACKGROUND

As the Critical Dimension (CD) of copper interconnections in BEOL becomes smaller and smaller, it becomes more and more difficult to fill trenches and openings of vias.

Refer to FIG. 1, which is a structural schematic view of a copper filled recess structure formed by adopting an existing first method for making the copper filled recess structure. The existing first method for making the copper filled recess structure adopts a Physical Vapor Deposition (PVD) TaN+Ta+Cu Seed process, and includes the following steps:

A recess 102 is formed on a dielectric layer, for example, an interlayer film 101. The recess 102 is a trench corresponding to a copper connection in a copper interconnection or a via opening corresponding to a via.

Then, a TaN layer 103 and a Ta layer 104 are formed by adopting a PVD process. A block layer is formed by superposing the TaN layer 103 and the Ta layer 104.

Then, a copper seed layer 105 is formed. Since the step covering ability of the copper seed layer 105 is poor, it is easy to produce an overhang effect at the top of the recess 102, that is, the copper seed layer 105 at the top of the recess 102 is thicker, such that the width d101 of the top of the recess 102 becomes smaller.

Then, an electrochemically-plated copper film 106 is formed by adopting an electrochemical process (ECP). Since the width d101 of the top of the recess 102 is small, the difficulty in forming the electrochemically-plated copper film 106 is increased. The existing first method cannot be applied to recess filling at a technology node of less than 14 nm, because the critical dimension of the copper connection in the copper interconnection corresponding to a semiconductor device at a process node of 14 nm is about 32 nm, and after the copper seed layer 105 is deposited, the width d101 of the top of the recess 102 is too small to meet the requirement of the ECP process. If the width d101 is increased by decreasing the thickness of the copper seed layer 105, the copper on the side surfaces of the recess 102 cannot form a continuous structure.

Refer to FIG. 2, which is a structural schematic view of a copper filled recess structure formed by adopting an existing second method for making a copper filled recess structure. In order to overcome the defect that the existing first method for making the copper filled recess structure described above can no longer use the technology node of less than 14 nm, a metal cobalt (Co) Chemical Vapor Deposition (CVD) process is introduced into the process of the technology node of 14 nm, and a metal cobalt layer is used to replace the Ta layer, that is, a PVD TaN+CVD Co+Cu Seed process is adopted. The existing second method for making the copper filled recess structure includes the following steps:

A recess 202 is formed on a dielectric layer, for example, an interlayer film 102. The recess 202 is a trench corresponding to a copper connection in a copper interconnection or a via opening corresponding to a via.

Then, a TaN layer 203 is formed by adopting a PVD process.

Then, a cobalt layer 204 is formed by adopting a CVD process.

Then, a copper seed layer 205 is formed. Since the step covering ability of the copper seed layer 205 is poor, after the copper seed layer 205 is adopted, it is still easy to produce a overhang effect at the top of the recess 202, that is, the copper seed layer 205 at the top of the recess 202 is thicker, such that the width d201 of the top of the recess 102 becomes smaller.

Then, an electrochemically-plated copper film 206 is formed by adopting an electrochemical plating process (ECP).

The main functions of the cobalt layer 204 are to improve the adhesion property of Cu, prevent the agglomeration effect of Cu in case of small thickness, and guarantee that the copper on the side surfaces of the recess is continuous in case of very small thickness. In other words, the thickness of the copper seed layer 205 can be reduced by adopting the cobalt layer 204. Since the thickness of the copper seed layer 205 in FIG. 2 is smaller than the thickness of the copper seed layer 105 in FIG. 1, the width d201 in FIG. 2 will be greater than the width d101 in FIG. 1 after the copper seed layer is formed under the situation that the top opening width of the recess 202 is the same as the top opening width of the recess 102. Therefore, the existing second method for making the copper filled recess structure can be applied to the process of the technology node of 14 nm, but the existing first method for making the copper filled recess structure cannot be applied to the process of the technology node of 14 nm.

Although the thickness of the required copper seed layer 205 can be effectively reduced after the Co liner layer, i.e., the cobalt layer 204, is introduced in the existing second method for making the copper filled recess structure, the contribution of the copper seed layer 205 to the reduction of the dimension of the top opening of the recess 202 is still very great. At the technology node of 14 nm, the dimension of the opening is reduced by 7.9 nm.

### BRIEF SUMMARY

The technical problem to be solved by the present application is to provide a copper filled recess structure. Since a copper layer in the present application does not contain a copper seed layer and completely consists of an electrochemically-plated copper film, the ability of filling copper in a recess can be improved, the reduction of the dimension of the copper filled recess structure is facilitated, and it is especially suitable for use as a copper connection and a via at a process node of less than 14 nm. For this purpose, the present application further discloses a method for making the copper filled recess structure.

In order to solve the technical problem, the copper filled recess structure provided by the present application includes:

a recess formed in a first dielectric layer;

a block layer is formed on the bottom surface and side surfaces of the recess;

a cobalt layer is formed on the surface of the block layer and a ruthenium layer is formed on the surface of the cobalt layer;

a copper layer completely fills the recess on which the block layer, the cobalt layer and the ruthenium layer are formed, so as to form the copper filled recess structure;

the copper layer completely consists of an electrochemically-plated copper film;

a supportive nucleation film layer of the copper layer is formed by superposing the cobalt layer and the ruthenium layer;

the supportive nucleation film layer enables the copper layer to have a structure in which the electrochemically-plated copper film and the ruthenium layer are in direct contact, such that a region filled with the electrochemically-plated copper film is a region surrounded by the supportive nucleation film layer.

As a further improvement, the recess is a trench and the copper filled recess structure is a copper interconnection;

or the recess is an opening of a via and the copper filled recess structure is the via.

As a further improvement, the first dielectric layer is an interlayer film.

As a further improvement, the barrier layer is a single layer of TaN or TiN, or a multilayer composed of TaN and Ta or TiN and Ti.

As a further improvement, the thickness of the cobalt layer is 5 Å-30 Å.

As a further improvement, the thickness of the ruthenium layer is 5 Å-40Å.

As a further improvement, the interlayer film is formed on a semiconductor substrate, a semiconductor device is formed on the semiconductor substrate, and the copper interconnection forms an electrode leading-out structure of the semiconductor device.

As a further improvement, the process node of the semiconductor device is less than 14 nm.

In order to solve the technical problem, the method for making the copper filled recess structure provided by the present application includes the following steps:

step 1: forming a recess in a first dielectric layer;

step 2: forming a block layer on the bottom surface and side surfaces of the recess;

step 3: forming a cobalt layer on the surface of the block layer;

step 4: forming a ruthenium layer on the surface of the cobalt layer,

a supportive nucleation film layer of the copper layer being formed by superposing the cobalt layer and the ruthenium layer;

step 5: directly performing a copper electrochemical plating process to form a copper layer completely consisting of an electrochemically-plated copper film on the supportive nucleation film layer, the copper layer completely filling the recess on which the block layer, the cobalt layer and the ruthenium layer are formed, so as to form the copper filled recess structure.

As a further improvement, the recess is a trench and the copper filled recess structure is a copper interconnection;

or the recess is an opening of a via and the copper filled recess structure is the via.

As a further improvement, the first dielectric layer is an interlayer film.

As a further improvement, the barrier layer is a single layer of TaN or TiN, or a multilayer composed of TaN and Ta or TiN and Ti.

As a further improvement, the thickness of the cobalt layer is 5 Å-30 Å.

As a further improvement, the thickness of the ruthenium layer is 5 Å-40 Å.

As a further improvement, the interlayer film is formed on a semiconductor substrate, a semiconductor device is formed on the semiconductor substrate, and the copper interconnection forms an electrode leading-out structure of the semiconductor device.

As a further improvement, the process node of the semiconductor device is less than 14 nm.

In the copper filled recess structure provided by the present application, the supportive nucleation film layer of the copper layer formed by superposing the cobalt layer and the ruthenium layer is adopted before the electrochemically-plated copper film is formed. Since the ruthenium layer has low electrochemical potential energy, copper electrochemical plating can be directly performed on the ruthenium layer. Moreover, ruthenium oxide, i.e., RuOx, has good conductivity, so even if ruthenium is oxidized in acidic ECP solution, it will not affect the conductivity of the copper filled recess structure. However, if the ruthenium layer is used alone to form the copper layer, the reliability is poor, so the ruthenium layer cannot be used as the supportive nucleation layer of the electrochemically-plated copper film.

In addition, just as the ruthenium layer facilitates copper nucleation, the cobalt layer also facilitates copper nucleation, that is, the cobalt layer and the ruthenium layer both facilitate copper nucleation. However, Co is not compatible with acidic ECP solution, it is easily dissolved and the oxide of Co is not conductive, which makes the conductivity of the whole copper filled recess structure be poor when the cobalt layer is used alone to form the copper layer, so the cobalt layer cannot be used alone as the supportive nucleation film layer of the electrochemically-plated copper film.

By combining the cobalt layer with the ruthenium layer and providing the ruthenium layer between the cobalt layer and the copper layer, the present application can overcome the defect that the ruthenium layer or the cobalt layer provided alone cannot be used as the supportive nucleation film layer of the electrochemically-plated copper film, and finally the electrochemically-plated copper film with good reliability can be obtained without adopting the copper seed crystal layer, thus overcoming the defect that the filling of the electrochemically-plated copper film is not facilitated due to the reduction of the opening of the recess which is easily caused by the use of the copper seed layer, such that the ability of filling copper in the recess can be improved, the process window of filling copper in the recess can be improved, the reliability can be kept excellent at the same time, the reduction of the dimension of the copper filled recess structure is facilitated, and it is especially suitable for use as a copper connection and a via at a process node of less than 14 nm.

### BRIEF DESCRIPTION OF THE DRAWINGS

The present application will be further described below in detail in combination with the embodiments with reference to the drawings.

FIG. 1 is a structural schematic view of a copper filled recess structure formed by adopting an existing first method for making the copper filled recess structure.

FIG. 2 is a structural schematic view of a copper filled recess structure formed by adopting an existing second method for making the copper filled recess structure.

FIG. 3 is a structural schematic view of a copper filled recess structure according to one embodiment of the present application.

FIG. 4 is a flowchart of a method for making a copper filled recess structure according to one embodiment of the present application.

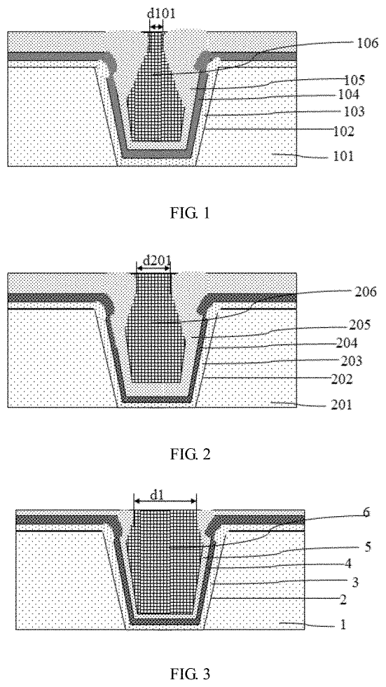

### DETAILED DESCRIPTION OF THE APPLICATOIN

Referring to FIG. 3, it is a structural schematic view of a copper filled recess structure according to one embodiment of the present application. The copper filled recess structure according to one embodiment of the present application includes:

a recess 2 formed in a first dielectric layer 1.

A block layer 3 is formed on the bottom surface and side surfaces of the recess 2.

In one embodiment of the present application, the block layer 3 is a TaN layer. In other embodiments, the block layer 3 may also be a TiN layer or a multilayer composed of TaN and Ta or TiN and Ti.

A cobalt layer 4 is formed on the surface of the block layer 3 and a ruthenium layer 5 is formed on the surface of the cobalt layer 4.

A copper layer 6 completely fills the recess 2 on which the block layer 3, the cobalt layer 4 and the ruthenium layer 5 are formed, so as to form the copper filled recess structure.

The copper layer 6 completely consists of an electrochemically-plated copper film.

A supportive nucleation film layer of the copper layer 6 is formed by superposing the cobalt layer 4 and the ruthenium layer 5.

The supportive nucleation film layer enables the copper layer 6 to have a structure in which the electrochemically-plated copper film and the ruthenium layer 5 are in direct contact, such that a region filled with the electrochemically-plated copper film is a region surrounded by the supportive nucleation film layer. From FIG. 3, it can be seen that there is no copper seed layer in the copper layer 6, thus overcoming a overhang effect produced by the copper seed layer and preventing the top opening of the recess 2 from being decreased due to the overhang effect of the copper seed layer, such that the width d1 of the top opening of the recess 2 can be kept to be greater, the filling of the electrochemically-plated copper film of the copper layer 6 is facilitated, and the filling process window and filling quality can be improved.

In one embodiment of the present application, the first dielectric layer 1 is an interlayer film.

The interlayer film is formed on a semiconductor substrate, a semiconductor device is formed on the semiconductor substrate, and the copper interconnection forms an electrode leading-out structure of the semiconductor device.

The process node of the semiconductor device is less than 14 nm.

The recess 2 is a trench and the copper filled recess structure is a copper interconnection;

or the recess 2 is an opening of a via and the copper filled recess structure is the via.

The thickness of the cobalt layer 4 is 5 Å-30 Å.

The thickness of the ruthenium layer 5 is 5 Å-40 Å.

In the copper filled recess structure provided by the embodiment of the present application, the supportive nucleation film layer of the copper layer 6 formed by superposing the cobalt layer 4 and the ruthenium layer 5 is adopted before the electrochemically-plated copper film is formed. Since the ruthenium layer has low electrochemical potential energy, copper electrochemical plating can be directly performed on the ruthenium layer 5. Moreover, ruthenium oxide, i.e., RuOx, has good conductivity, so even if ruthenium is oxidized in acidic ECP solution, it will not affect the conductivity of the copper filled recess structure. However, if the ruthenium layer 5 is used alone to form the copper layer 6, the reliability is poor, so the ruthenium layer 5 cannot be used as the supportive nucleation layer of the electrochemically-plated copper film.

In addition, just as the ruthenium layer 5 facilitates copper nucleation, the cobalt layer 4 also facilitates copper nucleation, that is, the cobalt layer 5 and the ruthenium layer 5 both facilitate copper nucleation. However, Co is not compatible with acidic ECP solution, it is easily dissolved and the oxide of Co is not conductive, which makes the conductivity of the whole copper filled recess structure be poor when the cobalt layer 4 is used alone to form the copper layer 6, so the cobalt layer 4 cannot be used alone as the supportive nucleation film layer of the electrochemically-plated copper film.

By combining the cobalt layer 4 with the ruthenium layer 5 and providing the ruthenium layer 5 between the cobalt layer 4 and the copper layer 6, the embodiment of the present application can overcome the defect that the ruthenium layer 5 or the cobalt layer 5 provided alone cannot be used as the supportive nucleation film layer of the electrochemically-plated copper film, and finally the electrochemically-plated copper film with good reliability can be obtained without adopting the copper seed crystal layer, thus overcoming the defect that the filling of the electrochemically-plated copper film is not facilitated due to the reduction of the opening of the recess 2 which is easily caused by the use of the copper seed layer, such that the ability of filling copper in the recess 2 can be improved, the process window of filling copper in the recess 2 can be improved, the reliability can be kept excellent at the same time, the reduction of the dimension of the copper filled recess structure is facilitated, and it is especially suitable for use as a copper connection and a via at a process node of less than 14 nm.

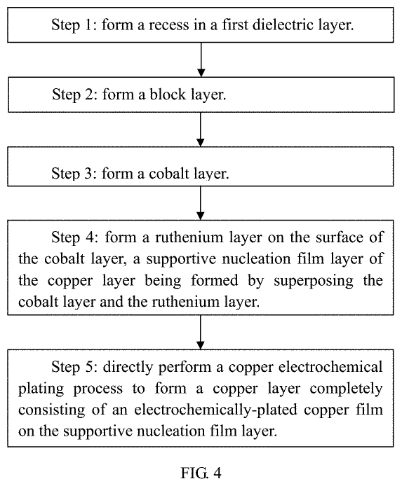

Referring to FIG. 4, it is a flowchart of a method for making the copper filled recess structure according to one embodiment of the present application. The copper filled recess structure formed by adopting the method for making the copper filled recess structure according to one embodiment of the present application is as illustrated in FIG. 3. The method for making the copper filled recess structure according to one embodiment of the present application includes the following steps:

In step 1, a recess 2 is formed in a first dielectric layer 1.

In step 2, a block layer 3 is formed on the bottom surface and side surfaces of the recess 2.

In one embodiment of the present application, the block layer 3 is a TaN layer. In other embodiments, the block layer 3 may also be a TiN layer or a multilayer composed of TaN and Ta or TiN and Ti.

In step 3, a cobalt layer 4 is formed on the surface of the block layer 3.

In step 4, a ruthenium layer 5 is formed on the surface of the cobalt layer 4.

A supportive nucleation film layer of the copper layer 6 is formed by superposing the cobalt layer 4 and the ruthenium layer 5.

In step 5, a copper electrochemical plating process is directly performed to form a copper layer 6 completely consisting of an electrochemically-plated copper film on the supportive nucleation film layer. The copper layer 6 completely fills the recess 2 on which the block layer 3, the cobalt layer 4 and the ruthenium layer 5 are formed, so as to form the copper filled recess structure.

In the method according to one embodiment of the present application, the first dielectric layer 1 is an interlayer film.

The interlayer film is formed on a semiconductor substrate, a semiconductor device is formed on the semiconductor substrate, and the copper interconnection forms an electrode leading-out structure of the semiconductor device.

The process node of the semiconductor device is less than 14 nm.

The recess 2 is a trench and the copper filled recess structure is a copper interconnection;

or the recess 2 is an opening of a via and the copper filled recess structure is the via.

The thickness of the cobalt layer 4 is 5 Å-30 Å.

The thickness of the ruthenium layer 5 is 5 Å-40 Å.

Compared with the existing first method for making the copper filled recess structure and the existing second method for making the copper filled recess structure, it can be seen that the method for making the copper filled recess structure according to one embodiment of the present application adopts a TaN+Co+Ru process, for reasons as follows:

Both Co and Ru facilitate the nucleation of Cu. However, Co is not compatible with acidic ECP bath and is easily dissolved. Moreover, the oxide of Co is not conductive. Therefore, in the method according to one embodiment of the present application, the cobalt layer 4 is placed on the lower layer of the ruthenium layer 5. However, the electrochemical potential energy of the ruthenium layer 5 is low, and even electroless deposited (ELD) copper plating can be performed. In addition, the conductivity of the oxide of the ruthenium layer 5 (RuOx) is very good, so the top layer in the method according to one embodiment of the present is the ruthenium layer 5. However, since the reliability of the ruthenium layer 5, i.e., ElectroMigration (EM) of metals, is poor, and Co can significantly improve the reliability (EM), this is the reason why Co exists.

Finally, the method according to one embodiment of the present application can increase the process window (Cu gapfill window) of the copper filled recess at the technology node of less than 14 nm, is applicable to BEOL interconnection technologies of smaller dimension, and can keep excellent EM performance at the same time.

The present application has been described above in detail through the specific embodiments, which, however, do not constitute limitations to the present application. Without departing from the principle of the present application, those skilled in the art may make many modifications and improvements, which should also be regarded as included in the scope of protection of the present application.

What is claimed is:

1. A copper filled recess structure, wherein the copper filled recess structure comprises:
a recess formed in a first dielectric layer;
a block layer is formed on the bottom surface and side surfaces of the recess;
a cobalt layer is formed on the surface of the block layer and a ruthenium layer is formed on the surface of the cobalt layer;
a copper layer completely fills the recess on which the block layer, the cobalt layer and the ruthenium layer are formed, so as to form the copper filled recess structure;
the copper layer completely consists of an electrochemically-plated copper film;
a supportive nucleation film layer of the copper layer is formed by superposing the cobalt layer and the ruthenium layer;
the supportive nucleation film layer enables the copper layer to have a structure in which the electrochemically-plated copper film and the ruthenium layer are in direct contact, such that a region filled with the electrochemically-plated copper film is a region surrounded by the supportive nucleation film layer.

2. The copper filled recess structure according to claim 1, wherein the recess is a trench and the copper filled recess structure is a copper interconnection;
or the recess is an opening of a via and the copper filled recess structure is the via.

3. The copper filled recess structure according to claim 2, wherein the first dielectric layer is an interlayer film.

4. The copper filled recess structure according to claim 1, wherein the barrier layer is a single layer of TaN or TiN, or a multilayer composed of TaN and Ta or TiN and Ti.

5. The copper filled recess structure according to claim 1, wherein the thickness of the cobalt layer is 5 Å-30 Å.

6. The copper filled recess structure according to claim 5, wherein the thickness of the ruthenium layer is 5 Å-40 Å.

7. The copper filled recess structure according to claim 3, wherein the interlayer film is formed on a semiconductor substrate, a semiconductor device is formed on the semiconductor substrate, and the copper interconnection forms an electrode leading-out structure of the semiconductor device.

8. The copper filled recess structure according to claim 7, wherein the process node of the semiconductor device is less than 14 nm.

9. A method for making a copper filled recess structure, wherein the method for making the copper filled recess structure comprises the following steps:
step 1: forming a recess in a first dielectric layer;
step 2: forming a block layer on the bottom surface and side surfaces of the recess;
step 3: forming a cobalt layer on the surface of the block layer;
step 4: forming a ruthenium layer on the surface of the cobalt layer,
a supportive nucleation film layer of the copper layer being formed by superposing the cobalt layer and the ruthenium layer; and
step 5: directly performing a copper electrochemical plating process to form a copper layer completely consisting of an electrochemically-plated copper film on the supportive nucleation film layer, the copper layer completely filling the recess on which the block layer, the cobalt layer and the ruthenium layer are formed, so as to form the copper filled recess structure.

10. The method for making the copper filled recess structure according to claim 9, wherein the recess is a trench and the copper filled recess structure is a copper interconnection;
or the recess is an opening of a via and the copper filled recess structure is the via.

11. The method for making the copper filled recess structure according to claim 10, wherein the first dielectric layer is an interlayer film.

12. The method for making the copper filled recess structure according to claim 9, wherein the barrier layer is a single layer of TaN or TiN, or a multilayer composed of TaN and Ta or TiN and Ti.

13. The method for making the copper filled recess structure according to claim 9, wherein the thickness of the cobalt layer is 5 Å-30 Å.

14. The method for making the copper filled recess structure according to claim 13, wherein the thickness of the ruthenium layer is 5 Å-40 Å.

15. The method for making the copper filled recess structure according to claim 11, wherein the interlayer film is formed on a semiconductor substrate, a semiconductor device is formed on the semiconductor substrate, and the copper interconnection forms an electrode leading-out structure of the semiconductor device.

16. The method for making the copper filled recess structure according to claim 15, wherein the process node of the semiconductor device is less than 14 nm.
